(19) United States
(12) Patent Application Publication
(10) Pub. No.: US 2015/0048731 A1
(43) Pub. Date: Feb. 19, 2015

(54) MOVABLE CONTROL PANEL TO ALLOW SERVICE ACCESS TO BUILT-IN DOMESTIC APPLIANCE WITHOUT REMOVING APPLIANCE FROM BUILT-IN POSITION

(71) Applicant: BSH Home Appliances Corporation, Irvine, CA (US)

(72) Inventors: Michael Penuel, Swansboro, NC (US); Jana Zeigler, New Bern, NC (US)

(73) Assignee: BSH Home Appliances Corporation, Irvine, CA (US)

(21) Appl. No.: 13/965,251

(22) Filed: Aug. 13, 2013

(51) Int. Cl. H05K 5/00; H05K 5/02

(52) U.S. Cl. CPC H05K 5/0017; H05K 5/02
USPC 312/326; 312/223.1

(57) ABSTRACT

A domestic appliance and cabinet combination is provided. The combination includes a cabinet having a recess and a domestic appliance positioned in the recess. The appliance has a control panel attached to the appliance body by a control panel movement mechanism; electronic devices electrically connected to the control panel; a stationary element fixed to the appliance body; and an electronics support element on which the electronic devices are mounted, the electronics support element being slidingly attached to the stationary element such that the electronics support element can slide in a direction from the back side to the front side while remaining attached to the stationary element. The electronics support element slides from a retracted position to an extended position when the control panel is in the open position, and the extended position of the electronics support element is a service position in which the electronic devices can be serviced.

### FIELD OF THE INVENTION

The invention is directed to a domestic appliance. More particularly, the invention is directed to a built-in domestic appliance having a movable control panel to allow service access to electronic components without removing the appliance from its built-in position.

An example of an application for the invention is a built-in domestic oven having a control panel behind which electronic components are mounted on a slidable plate that is exposed when the control panel is moved to a service position.

### BACKGROUND OF THE INVENTION

In some modern kitchens, built-in appliances are used to conserve space and to provide an aesthetically pleasing look. Such appliances can include, for example, conventional ovens, microwave ovens, and steam ovens. These appliances are often very heavy and/or built in to expensive, furniture like, cabinets. Often such an appliance must be at least partially removed from its cabinet in order for the appliance to be serviced. Such removal can be difficult and often requires two service technicians and, as a result, is expensive and can easily result in damage to the cabinet.

Many modern appliances have electronic control elements. Access to these electronic control elements is often necessary in order to diagnose and/or repair the appliance.

In light of the above, there is a need for a system that allows access to electronic control elements without having to remove the appliance from its cabinet.

### SUMMARY

The invention achieves the benefit of providing a domestic appliance having a control panel that is movable from a normal operating position to an open position that allows access to electronic components and other serviceable elements of the appliance. Because the controls of the control panel often need to be operated during access to the electronic components and other serviceable elements, particular embodiments of the invention provide for the control panel to be operational while in the open position. In addition, particular embodiments mount the electronic components and other serviceable elements on a sliding platform that can be extended outwardly from its normal operating position to a position that is more accessible to a service technician when the control panel is in the open position.

Particular embodiments of the invention are directed to a domestic appliance and cabinet combination that includes a cabinet having a recess; and a domestic appliance positioned in the recess in a normal operating position. The domestic appliance has an appliance body having a back side and a front side; a control panel located at the front side of the appliance body and having controls for controlling the appliance, the control panel being attached to the appliance body by a control panel movement mechanism; electronic devices electrically connected to the control panel; a stationary element fixed to the appliance body; and an electronics support element on which the electronic devices are mounted, the electronics support element being slidingly attached to the stationary element such that the electronics support element can slide in a direction from the back side to the front side while remaining attached to the stationary element. The control panel movement mechanism allows the control panel to move between a closed position to an open position while the appliance is in the normal operating position in the recess, the electronics support element is adapted to slide from a retracted position to an extended position in the direction from the back side to the front side when the control panel is in the open position, the retracted position of the electronics support element is a normal operation position, and the extended position of the electronics support element is a service position in which the electronic devices can be serviced.

Other embodiments of the invention are directed to a domestic appliance adapted to be positioned in a recess of a cabinet. The domestic appliance has an appliance body having a back side and a front side, the back side adapted to be located in the recess when the appliance is in a normal operating position; a control panel located at the front side of the appliance body and having controls for controlling the appliance, the control panel being attached to the appliance body by a control panel movement mechanism; electronic devices electrically connected to the control panel; a stationary element fixed to the appliance body; and an electronics support element on which the electronic devices are mounted, the electronics support element being slidingly attached to the stationary element such that the electronics support element can slide in a direction from the back side to the front side while remaining attached to the stationary element. The control panel movement mechanism allows the control panel to move between a closed position to an open position, the electronics support element is adapted to slide from a retracted position to an extended position in the direction from the back side to the front side when the control panel is in the open position, the retracted position of the electronics support element is a normal operation position, and the extended position of the electronics support element is a service position in which the electronic devices can be serviced.

### BRIEF DESCRIPTION OF THE DRAWINGS

The following figures form part of the present specification and are included to further demonstrate certain aspects of the disclosed features and functions, and should not be used to limit or define the disclosed features and functions. Consequently, a more complete understanding of the exemplary embodiments and further features and advantages thereof may be acquired by referring to the following description taken in conjunction with the accompanying drawings, wherein:

FIG. 1 is a perspective view of a combination domestic appliance in accordance with embodiments of the invention;

FIG. 2 is a perspective partial view of an example of an embodiment of the invention from the rear in the closed position;

FIG. 3 is a perspective partial view of the embodiment of the invention shown in FIG. 2 from the rear in the open position;

FIG. 4 is a perspective partial view of the embodiment of the invention shown in FIGS. 2 and 3 from the front in the open position;

FIG. 5 is a bottom view of an example of an embodiment of the invention in a retracted position; and

FIG. 6 is a bottom view of the embodiment shown in FIG. 5 in an extended position.

### DETAILED DESCRIPTION

The invention is described herein with reference to the accompanying drawings in which exemplary embodiments of the invention are shown. The invention may, however, be embodied in many different forms and should not be construed as limited to the embodiments set forth herein.

As explained above, embodiments of the invention provide a domestic appliance having a control panel that is movable from a normal operating position to an open position that allows access to electronic components and other serviceable elements of the appliance. Because the controls of the control panel often need to be operated during access to the electronic components and other serviceable elements, particular embodiments of the invention provide for the control panel to be operational while in the open position. In addition, particular embodiments mount the electronic components and other serviceable elements on a sliding platform that can be extended outwardly from its normal operating position to a position that is more accessible to a service technician when the control panel is in the open position.

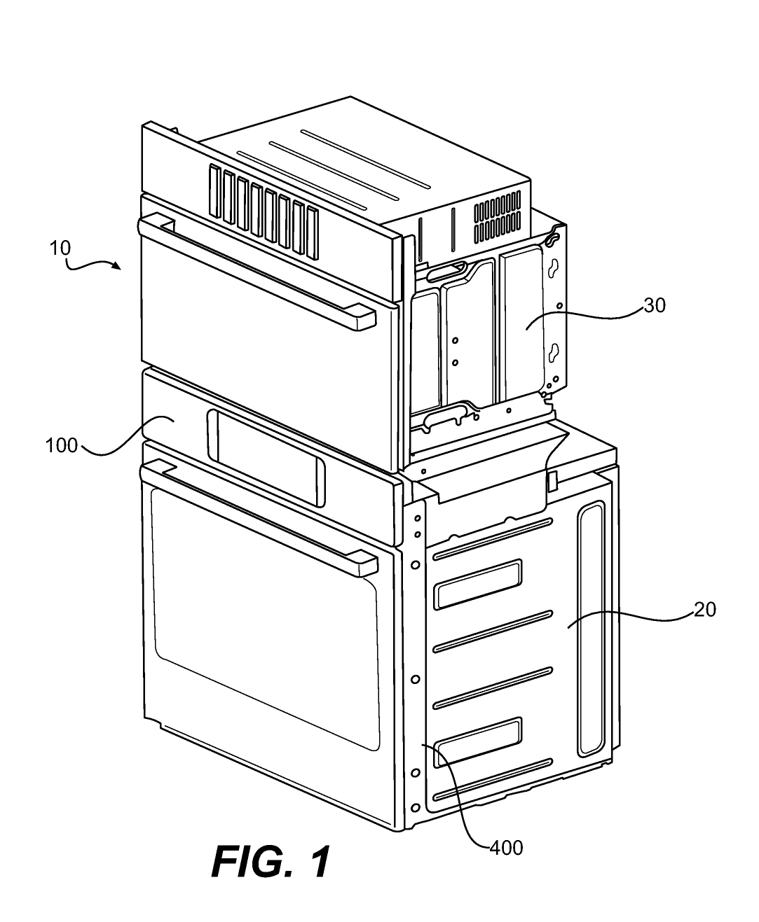

FIG. 1 shows an example of a stacked combination unit 10 including a lower appliance 20 and an upper appliance 30. In this example, lower appliance 20 is a built-in conventional oven having a control panel 100. Although this example shows a combination unit having a lower appliance being a conventional oven, it is noted that the invention also applies to individual appliances and appliances other than conventional ovens.

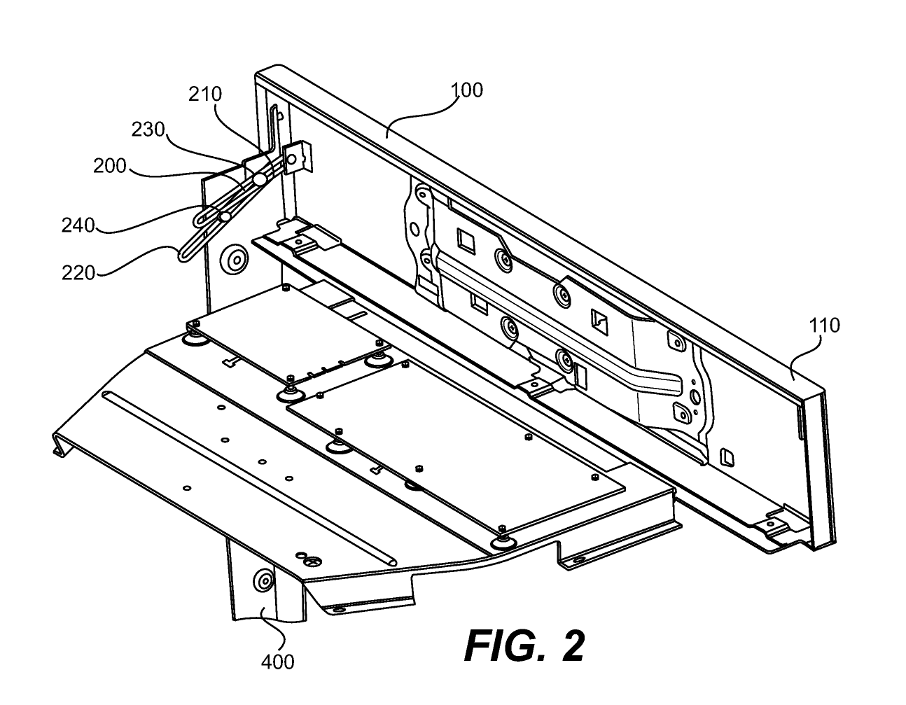

FIG. 2 is a partial view of the backside of control panel 100 with the majority of appliance 20 removed in order to clearly show particular elements of the invention. In this example, control panel 100 has a faceplate 110 that has a plurality of control elements such as, for example, control knobs, displays and pushbuttons. Control panel 100 is shown in FIG. 2 in a normal operating position, as is also shown in FIG. 1. In this example, control panel 100 is attached to the main body of appliance 20 (represented here by structure 400) by way of a control panel movement mechanism 200. Although only one control panel movement mechanism 200 is shown in FIG. 2, it is noted that a second control panel movement mechanism can be provided at the other end of control panel 100.

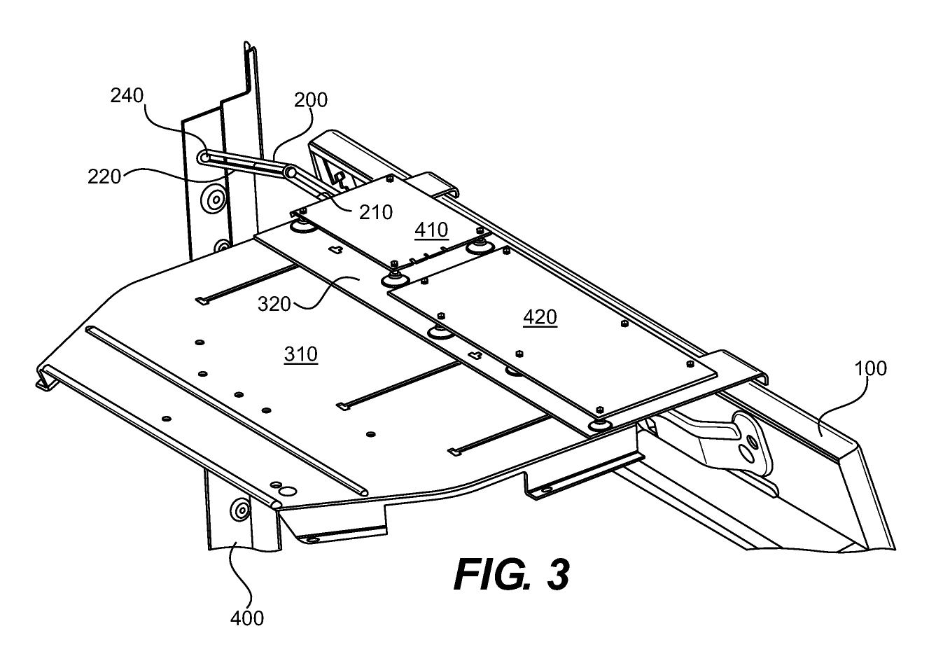

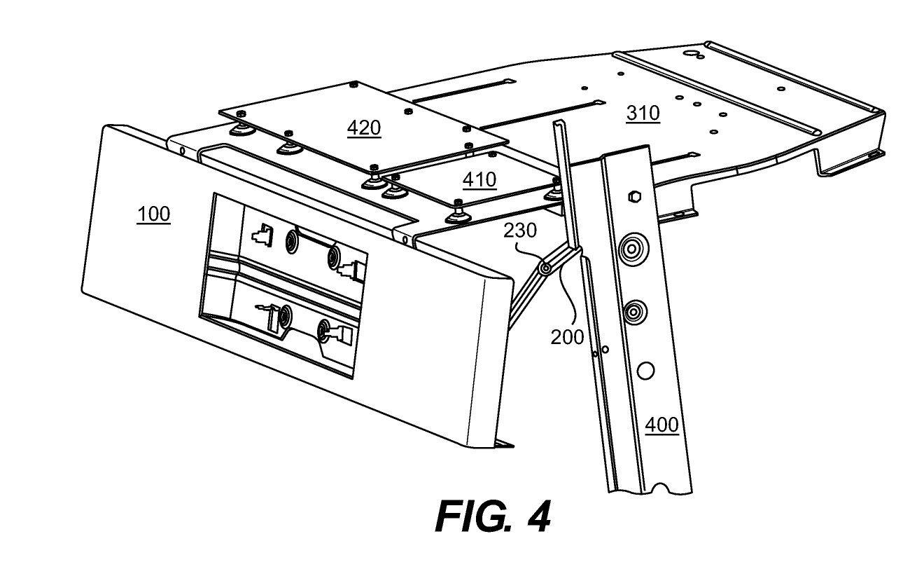

In this example, control panel movement mechanism 200 includes an arm 210 that is attached to the back side of control panel 100 and includes a slot that allows arm 210 to move relative to a pin 230. A second arm 220 is similar to arm 210 and has a slot that allows arm 220 to move relative to a pin 240 that is fixed to structure 400. Pin 230 is fixed relative to arm 220 and allows pivotable movement between arms 210 and 220. This movement is shown more clearly in FIGS. 3 and 4 that show control panel 100 in the open position.

As can be seen in FIGS. 3 and 4, when control panel 100 is moved from the closed position (as shown in FIG. 2) to the open position (as shown in FIGS. 3 and 4) control panel 100 moves forward and away from appliance 20 and downward to permit access to, in this example, two electronics support elements 410, 420 that are mounted on a sliding plate 320.

FIGS. 3 and 4 show sliding plate 320 in an extended position relative to a stationary plate 310. FIG. 2 shows sliding plate 320 in a retracted state relative to stationary plate 310. After control panel 100 is moved from the closed position to the open position, sliding plate 320 is pulled out by a service technician so that electronic components and other serviceable elements can be more easily accessed. Although omitted from the drawings for clarity, electrical connections between control panel 100 and electronic components on electronics support elements 410, 420 remain connected when control panel 100 is in the open position. As shown most clearly in FIG. 4, control panel 100 is oriented so that it's control elements (control knobs, displays and pushbuttons) are easily accessible and visible to the service technician when control panel 100 is in the open position. This orientation and continued operability of control panel 100 in the open position permits the service technician to test the operation of the appliance while the electronic components and other serviceable elements are accessible.

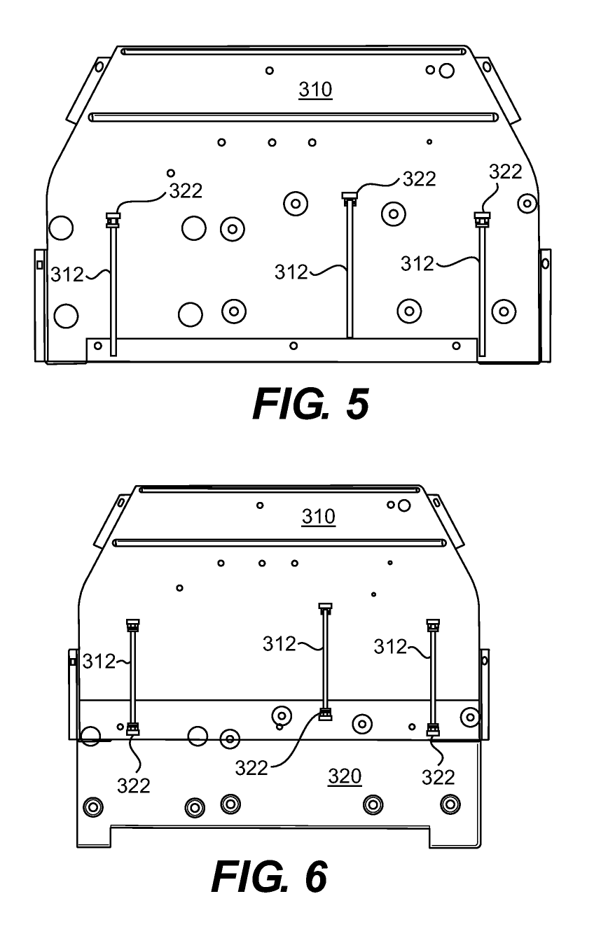

FIG. 5 shows a bottom view of stationary plate 310 with sliding plate 320 in the retracted position and FIG. 6 shows a bottom view of stationary plate 310 with sliding plate 320 in the extended position. In both FIGS. 5 and 6, slots 312 in stationary plate 310 are visible. T-tabs 322 which are connected to sliding plate 320 are shown engaging slots 312. The interaction between T-tabs 322 and slots 312 permit sliding plate 320 to slide relative to stationary plate 310 while still keeping sliding plate 320 securely positioned in a horizontal orientation.

By providing a control panel that can be moved away from the face of the cabinet in which the appliance is installed and then moved downward while still being electrically connected to the control circuitry of the appliance, simplified servicing and repair of the appliance are achieved. This movement of the control panel allows the control circuitry and other electronic components to be easily accessed as the sliding panel to which they are mounted can be pulled forward. These combined features make it possible for a single service technician to perform analysis and repairs on heavy appliances that would have, before the invention, required two or more service technicians due to the previous need to remove the appliance from its cabinet.

It will be appreciated that variants of the above-disclosed and other features and functions, or alternatives thereof, may be combined into many other different systems or applications. Various presently unforeseen or unanticipated alternatives, modifications, variations or improvements therein may be subsequently made by those skilled in the art which are also intended to be encompassed by the invention.

What is claimed is:

1. A domestic appliance and cabinet combination, comprising:
a cabinet having a recess; and
a domestic appliance positioned in the recess in a normal operating position, the domestic appliance having
an appliance body having a back side and a front side,
a control panel located at the front side of the appliance body and having controls for controlling the appliance, the control panel being attached to the appliance body by a control panel movement mechanism,
electronic devices electrically connected to the control panel,
a stationary element fixed to the appliance body, and
an electronics support element on which the electronic devices are mounted, the electronics support element being slidingly attached to the stationary element such that the electronics support element can slide in a direction from the back side to the front side while remaining attached to the stationary element,
wherein the control panel movement mechanism allows the control panel to move between a closed position to an open position while the appliance is in the normal operating position in the recess,
the electronics support element is adapted to slide from a retracted position to an extended position in the direction from the back side to the front side when the control panel is in the open position,
the retracted position of the electronics support element is a normal operation position, and
the extended position of the electronics support element is a service position in which the electronic devices can be serviced.

2. The combination of claim 1, wherein the controls for controlling the appliance are operational when the control panel is in the open position.

3. The combination of claim 2, wherein the electronic devices are operational when the electronics support element is in the extended position.

4. The combination of claim 3, wherein the control panel movement mechanism moves the control panel away from a face of the appliance when the control panel moves from the closed position to the open position.

5. The combination of claim 4, wherein a first movement of the control panel permitted by the control panel movement mechanism when the control panel moves from the closed position to the open position is a movement that is away from the face of the appliance.

6. The combination of claim 5, wherein the electronics support element has a plurality of T tabs that extend through slots in the stationary element to slidingly attach the electronics support element to the stationary element.

7. The combination of claim 6, wherein in the open position, a front face of the control panel faces at least partially in a direction in which the front face of the control panel faces when the control panel is in the closed position.

8. The combination of claim 7, wherein a direction in which the front face of the control panel faces in the open position is rotated no more than 45 degrees from the direction in which the front face of the control panel faces in the closed position.

9. The combination of claim 3, wherein the electronics support element has a plurality of T tabs that extend through slots in the stationary element to slidingly attach the electronics support element to the stationary element.

10. The combination of claim 9, wherein in the open position, a front face of the control panel faces at least partially in a direction in which the front face of the control panel faces when the control panel is in the closed position.

11. A domestic appliance adapted to be positioned in a recess of a cabinet, the domestic appliance comprising:
an appliance body having a back side and a front side, the back side adapted to be located in the recess when the appliance is in a normal operating position;
a control panel located at the front side of the appliance body and having controls for controlling the appliance, the control panel being attached to the appliance body by a control panel movement mechanism;
electronic devices electrically connected to the control panel;
a stationary element fixed to the appliance body; and
an electronics support element on which the electronic devices are mounted, the electronics support element being slidingly attached to the stationary element such that the electronics support element can slide in a direction from the back side to the front side while remaining attached to the stationary element,
wherein the control panel movement mechanism allows the control panel to move between a closed position to an open position,
the electronics support element is adapted to slide from a retracted position to an extended position in the direction from the back side to the front side when the control panel is in the open position,
the retracted position of the electronics support element is a normal operation position, and
the extended position of the electronics support element is a service position in which the electronic devices can be serviced.

12. The domestic appliance of claim 11, wherein the controls for controlling the appliance are operational when the control panel is in the open position.

13. The domestic appliance of claim 12, wherein the electronic devices are operational when the electronics support element is in the extended position.

14. The domestic appliance of claim 13, wherein the control panel movement mechanism moves the control panel away from a face of the appliance when the control panel moves from the closed position to the open position.

15. The domestic appliance of claim 14, wherein a first movement of the control panel permitted by the control panel movement mechanism when the control panel moves from the closed position to the open position is a movement that is away from the face of the appliance.

16. The domestic appliance of claim 15, wherein the electronics support element has a plurality of T tabs that extend through slots in the stationary element to slidingly attach the electronics support element to the stationary element.

17. The domestic appliance of claim 16, wherein in the open position, a front face of the control panel faces at least partially in a direction in which the front face of the control panel faces when the control panel is in the closed position.

18. The domestic appliance of claim 17, wherein a direction in which the front face of the control panel faces in the open position is rotated no more than 45 degrees from the direction in which the front face of the control panel faces in the closed position.

19. The domestic appliance of claim 13, wherein the electronics support element has a plurality of T tabs that extend through slots in the stationary element to slidingly attach the electronics support element to the stationary element.

20. The domestic appliance of claim 19, wherein in the open position, a front face of the control panel faces at least partially in a direction in which the front face of the control panel faces when the control panel is in the closed position.
